(19) United States
(12) Patent Application Publication
(10) Pub. No.: US 2023/0343729 A1
(43) Pub. Date: Oct. 26, 2023

(54) INTEGRATED INTERPOSER FOR RF APPLICATION

(71) Applicant: Avago Technologies International Sales Pte. Limited, Singapore (SG)

(72) Inventors: Xi Liu, San Jose, CA (US); Lea-Teng Lee, Sunnyvale, CA (US); William Snodgrass, Fort Collins, CO (US)

(21) Appl. No.: 17/726,286

(22) Filed: Apr. 21, 2022

(51) Int. Cl. H01L 23/66; H01L 23/498; H01L 25/16

(52) U.S. Cl. CPC H01L 23/66; H01L 23/49833; H01L 23/49822; H01L 23/49838; H01L 25/162; H01L 2223/6611; H01L 2223/6622; H01L 2223/665

(57) ABSTRACT

An interposer is described. The interposer includes a top layer including an array of passive devices integrated into the top layer. A number of the passive devices may be connected to a pad by a trace disposed above the top layer. The number of the passive devices may be selected to achieve a desired property for the array, such as a desired resistance, inductance, or capacitance. The interposer may thus provide an ability to rapidly tune a die coupled to the pad of the interposer based on the arrangement of the trace.

### TECHNICAL FIELD

The present invention generally relates to semiconductor devices, and more specifically to interposers.

### BACKGROUND

An RF module may include a die which is tuned by adjusting one or more properties of one or more passive devices. The passive devices may be discrete passive devices or components which are picked-and-placed on a printed circuit board. Following placement, the discrete passive devices may be soldered during reflow fabrication. The size of the discrete passive devices may be limited due to the pick-and-place fabrication and the reflow fabrication. In this regard, the machinery used to pick-and-place may include an accuracy at which the discrete passive device may be placed. Similarly, the machinery used to perform reflow fabrication may undesirably form bridges when the spacing between discrete passive devices is too small. Thus, a minimum spacing must be kept between the discrete passive devices to prevent accidental interconnection.

An important factor in the design of RF modules is size miniaturization. With 5G adoption and miniaturization trends, there is a need to reduce the dimensions of RF packages. Undesirably, the size of discrete passive devices is approaching a physical limit. In addition, due to footprint and spacing requirements, discrete passive components prohibit further package size reduction. However, such discrete passive devices may be indispensable to achieve the desired tuning of the die. Thus, the discrete passive devices may provide a limiting factor in reducing a size of the RF module. To integrate a die-based filter with a printed circuit board, the printed circuit board requires a large number of discrete passive devices. In some instances, the discrete passive devices may take up more space than the filter. Additionally, the discrete passive devices may not be placed on the printed circuit board under the die. Instead, the discrete passive devices are placed on the printed circuit board surrounding the die.

### SUMMARY

A package is disclosed, in accordance with one or more embodiments of the present disclosure. In one illustrative embodiment, the package includes a printed circuit board. In another illustrative embodiments, the package includes an interposer coupled to the printed circuit board. In another illustrative embodiment, the interposer includes a substrate including at least one via. In another illustrative embodiment, the interposer includes a multilayer structure disposed above the substrate. In another illustrative embodiment, the multilayer structure includes a top layer with an array including a plurality of passive devices integrated into at least one of the substrate or a dielectric of the multilayer structure. In another illustrative embodiment, the at least one via couples the plurality of passive devices to the printed circuit board. In another illustrative embodiment, the interposer includes a trace disposed above the multilayer structure and connecting at least one passive device of the plurality of passive devices to a pad disposed above the multilayer structure. In another illustrative embodiment, the array includes a property defined by the at least one passive device which is connected to the trace. In another illustrative embodiment, the package includes a die coupled to the pad.

An interposer is disclosed, in accordance with one or more embodiments of the present disclosure. In one illustrative embodiment, the interposer includes a substrate with at least one via. In another illustrative embodiment, the interposer includes a multilayer structure disposed above the substrate. In another illustrative embodiment, the multilayer structure includes a top layer with an array including a plurality of passive devices integrated into at least one of the substrate or a dielectric of the multilayer structure. In another illustrative embodiment, the at least one via couples the plurality of passive devices to a first pad on a bottom of the substrate by which the interposer is configured to couple to a printed circuit board. In another illustrative embodiment, the interposer includes a trace disposed above the multilayer structure and connecting at least one passive device of the plurality of passive devices to a second pad disposed above the multilayer structure by which the interposer is configured to couple to a die. In another illustrative embodiment, the array includes a property defined by the passive device which is connected to the trace.

A communication device is described, in accordance with one or more embodiments of the present disclosure. In one illustrative embodiment, the communication device includes a motherboard. In another illustrative embodiment, the communication device includes a radio frequency module. In another illustrative embodiment, the radio frequency module includes a printed circuit board coupled to the motherboard. In another illustrative embodiment, the radio frequency module includes an interposer coupled to the printed circuit board. In another illustrative embodiment, the interposer includes a substrate including at least one via. In another illustrative embodiment, the interposer includes a multilayer structure disposed above the substrate, the multilayer structure including a top layer with an array including a plurality of passive devices integrated into at least one of the substrate or a dielectric of the multilayer structure. In another illustrative embodiment, the at least one via couples the plurality of passive devices to the printed circuit board. In another illustrative embodiment, the interposer includes a trace disposed above the multilayer structure and connecting at least one passive device of the plurality of passive devices to a pad disposed above the multilayer structure. In another illustrative embodiment, the array includes a property defined by the passive device which is connected to the trace. In another illustrative embodiment, the radio frequency module includes a die coupled to the trace.

### BRIEF DESCRIPTION OF THE DRAWINGS

Implementations of the concepts disclosed herein may be better understood when consideration is given to the following detailed description thereof. Such description makes reference to the included drawings, which are not necessarily to scale, and in which some features may be exaggerated and some features may be omitted or may be represented schematically in the interest of clarity. Like reference numerals in the drawings may represent and refer to the same or similar element, feature, or function. In the drawings:

FIG. 1 depicts a side view of a package, in accordance with one or more embodiments of the present disclosure.

FIG. 2A depicts a top view of an interposer of a package with a die coupled to the interposer, in accordance with one or more embodiments of the present disclosure.

FIG. 2B depicts a top view of an interposer of a package including passive devices integrated into one or more layers of the interposer which may be accessed from a top surface of the interposer, in accordance with one or more embodiments of the present disclosure.

FIG. 2C depicts a simplified cross-section view of an interposer including passive devices integrated into one or more layers of the interposer which may be accessed from a top surface of the interposer, in accordance with one or more embodiments of the present disclosure.

FIG. 2D depicts a simplified cross-section view of an interposer including trench capacitors integrated into a substrate of the interposer which may be accessed from a top surface of the interposer, in accordance with one or more embodiments of the present disclosure.

FIG. 3 depicts a top view of an interposer with an extended trace for adjusting a property of a capacitor array, in accordance with one or more embodiments of the present disclosure.

FIG. 4 depicts a side view of a package including an interposer disposed in a cavity of a printed circuit board, in accordance with one or more embodiments of the present disclosure.

FIG. 5 depicts a side view of a package including a die coupled to passive components of an interposer by a wire-bond, in accordance with one or more embodiments of the present disclosure.

FIG. 6A depicts a simplified cross-section view of an interposer including a through via coupled to a passive device integrated into a top surface of the interposer, in accordance with one or more embodiments of the present disclosure.

FIG. 6B depicts a top view of an interposer including a through via coupled to a passive device integrated into a top surface of the interposer, in accordance with one or more embodiments of the present disclosure.

FIG. 7 depicts a simplified schematic of a communication device including a package, in accordance with one or more embodiments of the present disclosure.

### DETAILED DESCRIPTION OF THE INVENTION

Before explaining one or more embodiments of the disclosure in detail, it is to be understood that the embodiments are not limited in their application to the details of construction and the arrangement of the components or steps or methodologies set forth in the following description or illustrated in the drawings. In the following detailed description of embodiments, numerous specific details are set forth in order to provide a more thorough understanding of the disclosure. However, it will be apparent to one of ordinary skill in the art having the benefit of the instant disclosure that the embodiments disclosed herein may be practiced without some of these specific details. In other instances, well-known features may not be described in detail to avoid unnecessarily complicating the instant disclosure.

As used herein a letter following a reference numeral is intended to reference an embodiment of the feature or element that may be similar, but not necessarily identical, to a previously described element or feature bearing the same reference numeral (e.g., 1, 1a, 1b). Such shorthand notations are used for purposes of convenience only and should not be construed to limit the disclosure in any way unless expressly stated to the contrary.

Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of “a” or “an” may be employed to describe elements and components of embodiments disclosed herein. This is done merely for convenience and “a” and “an” are intended to include “one” or “at least one,” and the singular also includes the plural unless it is obvious that it is meant otherwise.

Finally, as used herein any reference to “one embodiment” or “some embodiments” means that a particular element, feature, structure, or characteristic described in connection with the embodiment is included in at least one embodiment disclosed herein. The appearances of the phrase “in some embodiments” in various places in the specification are not necessarily all referring to the same embodiment, and embodiments may include one or more of the features expressly described or inherently present herein, or any combination or sub-combination of two or more such features, along with any other features which may not necessarily be expressly described or inherently present in the instant disclosure.

Reference will now be made in detail to the subject matter disclosed, which is illustrated in the accompanying drawings. Embodiments of the present disclosure are generally directed to providing an interposer with integrated passive devices, which may also be referred to herein as integrated passives, passive devices, or integrated passive components. As used herein, the term integrated, integrating, and the like may refer to forming a component (e.g., a passive component) in one or more portions of an appropriate device, such as a metal layer, a dielectric, a multilayer structure, a substrate, and the like of an interposer or any other device. Integrating the passive devices in the interposer may be advantageous to reduce an in-plane dimension of the package. Furthermore, an array of the integrated passive devices may be integrated into one or more layers of the interposer for access from a top layer of the interposer. By being accessible from the top layer of the interposer, a trace connecting the integrated passive devices to a pad may be formed during a masking step to achieve a desired property. The property may include, but is not limited to, a capacitance, a resistance, or an inductance. Thus, the die may be tuned without requiring a redesign of the interposer. Instead, the interposer may achieve the desired property by masking the trace in a different arrangement. The interposer may then be coupled to a die and a printed circuit board to form a package. For example, the package may include, but is not limited to, a radio frequency (RF) module, an RF front end, and the like. As used herein the terms “coupled”, “coupling”, “connected,” “connecting,” and the like may allow for intervening layers, devices, or structures, unless indicated otherwise (e.g., “directly coupled”).

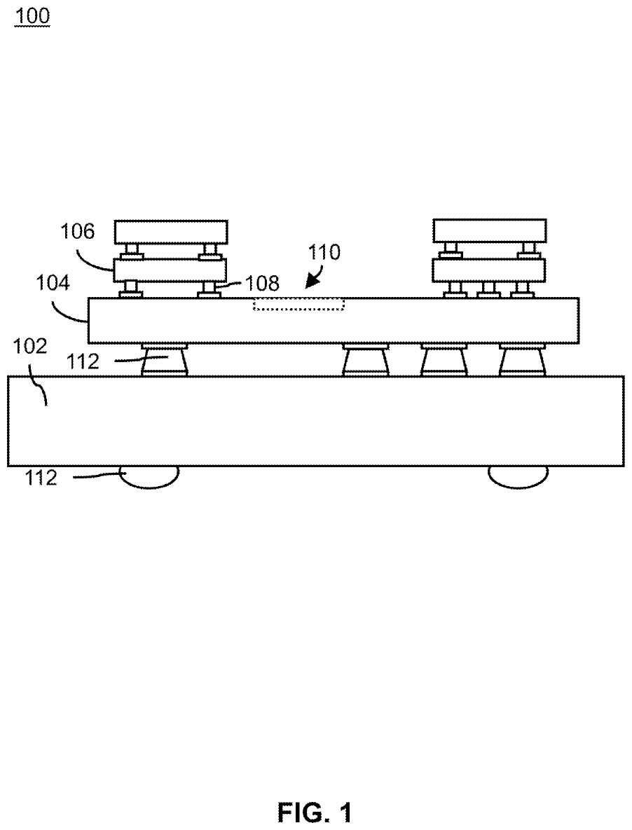

Referring generally to FIGS. 1-7, a package 100 is described in accordance with one or more embodiments of the present disclosure. The package 100 may include one or more components (e.g., passive, active, etc.) in an electronic system which affect electrons within the electronic system, such that the package may be considered an electronic package. As depicted in FIG. 1, the package 100 may include one or more of a printed circuit board 102 (PCB), an interposer 104, and one or more die 106. The interposer 104 may be coupled to the printed circuit board 102. Similarly, the die 106 may be coupled to the interposer 104. In this regard, the interposer 104 may be disposed between the die 106 and the printed circuit board 102. The interposer 104 may thus form an interface interposed between the die 106 and the printed circuit board 102 for routing signals between the die 106 and the printed circuit board 102. The interposer 104 may also be referred to as an interposer by being configured to interpose between the die 106 and the printed circuit board 102, even if the interposer 104 does not currently interface therebetween. The components of the package 100 may be coupled in any manner, such as, but not limited to, one or more interconnects 108 (e.g., copper pillars, solder bumps, gold bumps, etc.), solder balls 112, and the like for coupling the interposer 104 to the printed circuit board 102 and for coupling the die 106 to the interposer 104. For example, the solder balls 112 and interconnects 108 may be coupled between traces, pads, and the like which may be disposed on a surface of the associated printed circuit board 102, interposer 104, or die 106.

The package 100 may include multiple of the die 106 which are coupled to the interposer 104. The package 100 may also include one or more die 106 which are stacked on top of one another. Stacking the dies may reduce a footing requirement of the package 100. Furthermore, the package 100 may include any number of additional dies which may be coupled directly to the printed circuit board 102.

The die 106 may include, but is not limited to, a filter, a power amplifier, and the like. The package 100 may thus be used in a number of RF applications, such as, but not limited to, a radio frequency (RF) module of a mobile phone or another communication device. In such RF applications, designs of the package 100 may be sensitive to size and cost requirements. The die 106 may be electrically coupled to a number of passive devices to achieve a desired level of tuning. In embodiments, the interposer 104 includes passive devices 110 which are used to tune the die 106.

In embodiments, the interposer 104 includes one or more passive devices 110. The passive devices 110 are integrated with the interposer 104 during fabrication of the interposer. The interposer 104 may be fabricated using wafer-level technology. In this regard, the passive devices 110 may be integrated into one or more layers of a wafer. The wafer may then be cut to form the interposer 104. The passive devices 110 may be advantageous in reducing a size of the passive devices for the package 100, as compared to discrete passive components placed on the printed circuit board 102. Reducing the size of the passive devices 110 may be advantageous for reducing spacing requirements for tuning the die 106. By integrating the passive devices 110 in the interposer 104, the interposer 104 together with the integrated passive devices may also be placed under the die 106. This may be advantageous when compared to discrete passive components which may not be placed under the die 106 due to height constraints. Since the passives are integrated into the interposer, the clearance of the passive is no longer an issue. Additionally, the minimum distance between the integrated passive devices may be reduced, as compared to the use of discrete passive components, due to a reduced risk of the integrated passive devices accidentally interconnecting during fabrication of the metal layers. Placing the passive devices in the interposer 104 may thus reduce a footage requirement for the printed circuit board 102.

The passive devices 110 may include one or more of a resistor (e.g., thin-film resistor (TFR), etc.), a capacitor (e.g., metal-insulator-metal (MIM) capacitors, deep-trench capacitors (TC), metal-oxide-semiconductor (MOS) capacitor, metal fringe capacitors, etc.), or an inductor (e.g., a planar spiral inductor, etc.). As may be understood, the passive devices 110 may generally include any passive device which is suitable for integration into the interposer 104. Furthermore, the passive devices 110 may include any material, shape, and size for achieving the desired properties. The various passive devices described may be integrated into the interposer during one or more wafer fabrication steps. A property, such as, but not limited to, a resistance, a capacitance, or an inductance, may be selectively controlled based on the passive devices 110.

The interposer 104 may include the passive devices 110 without any active components (e.g., transistor, diodes, etc.) such that the interposer 104 is considered a passive interposer. The interposer 104 may then be connected to the die 106 which includes a number of passive and active components, such that the die 106 is considered an active die or an integrated circuit (IC) die.

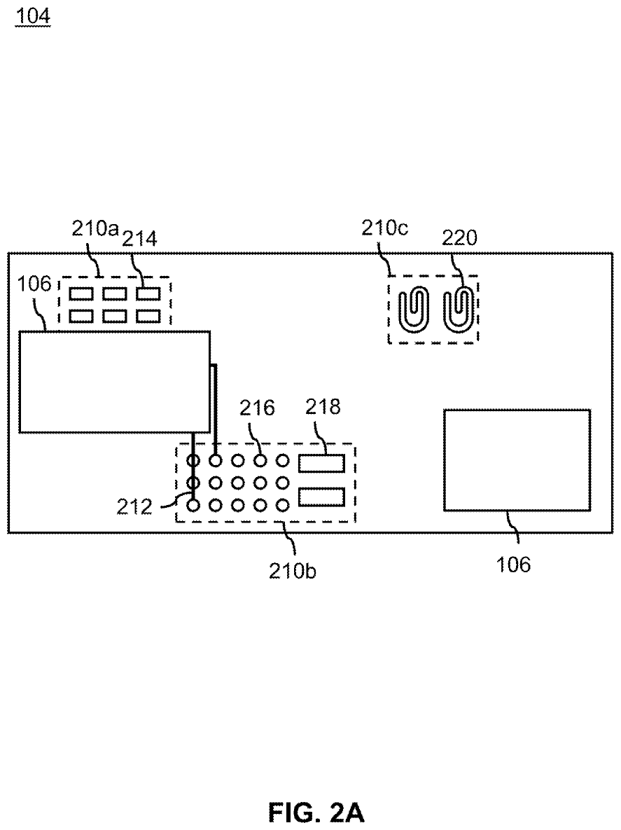

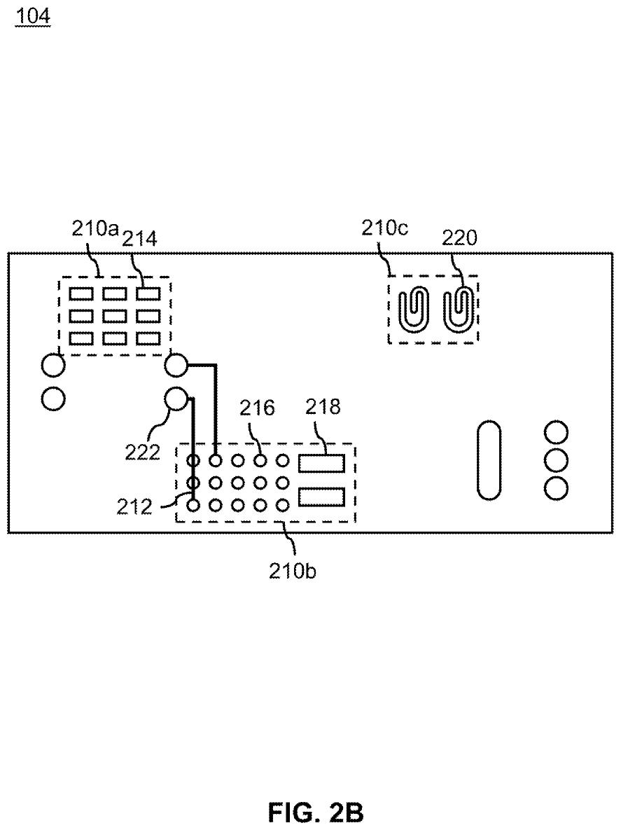

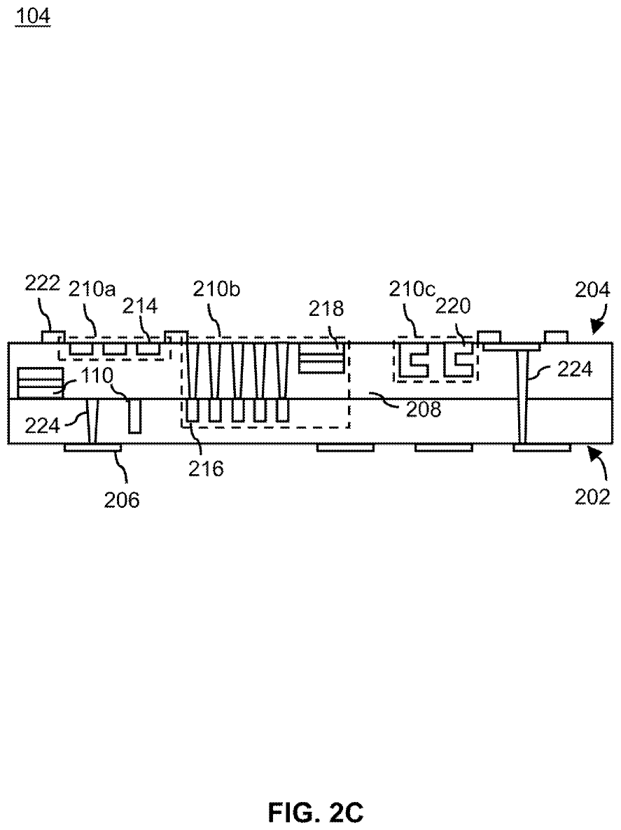

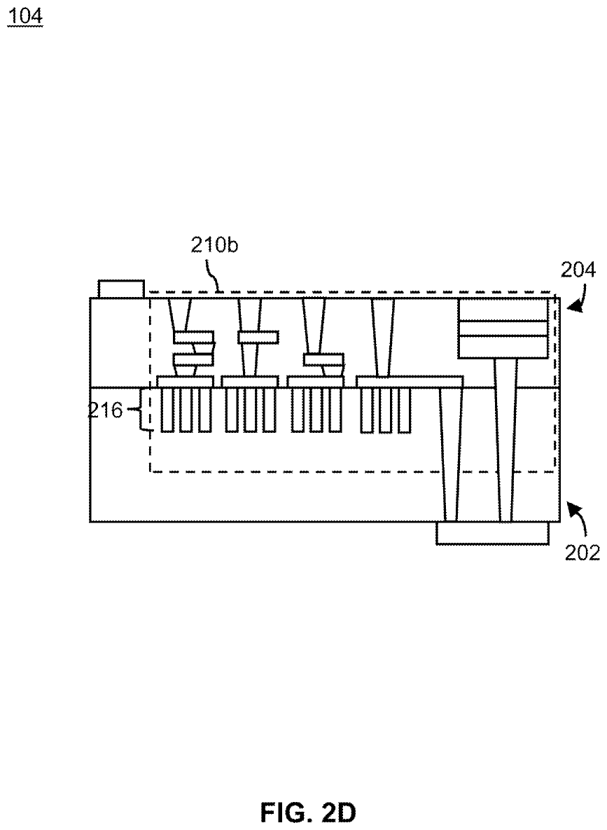

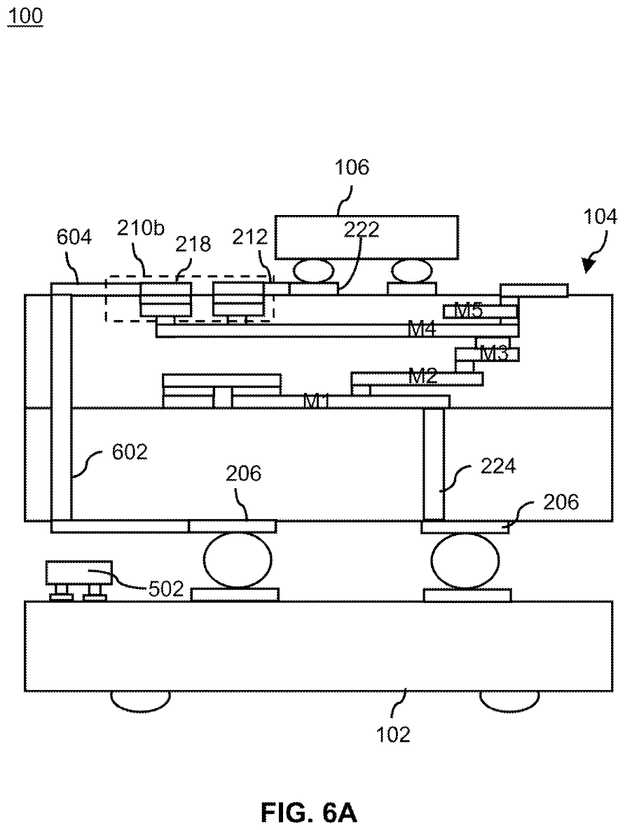

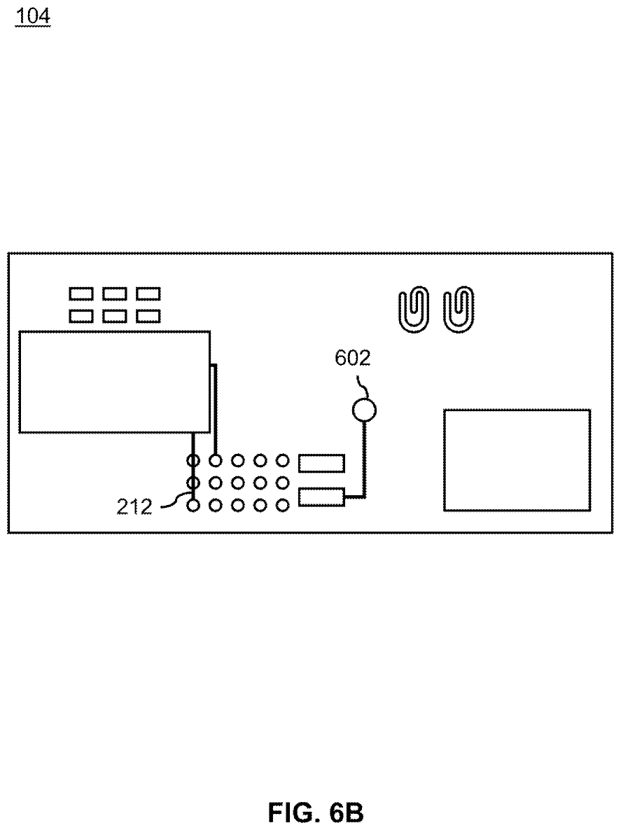

Referring now to FIGS. 2A-2D, one or more structures of the interposer 104 are described, in accordance with one or more embodiments of the present disclosure. The interposer may include a substrate 202 and a multilayer structure 204 disposed above the substrate 202. The substrate 202 may be a semiconductor material, such as, but not limited to, a silicon substrate or a glass substrate. The multilayer structure 204 may include a number of layers which include a metal trace surrounded by a dielectric 208. The metal trace may generally include any metal, such as, but not limited to, copper, aluminum, and the like. The dielectric 208 may be an organic material, such as, but not limited to, Benzocyclobutene (BCB), and the like. The multilayer structure 204 may include any number of the layers. The layers may be referred to the based on a position of the layer relative to the substrate 202: a first metal layer may be referred to as a metal 1 (M1) layer, a second layer may be referred to as metal 2 (M2) layer, and so on. For example, the multilayer structure 204 may include five metals layers (M1-M5) or more (see FIG. 6A), although this is not intended to be limiting. Connections may be made across the substrate 202 and one or more layers of the multilayer structure 204 by one or more vias 224. The vias 224 may be provided to connect the printed circuit board 102 to the die 106, by way of one or more pads 206 disposed on a bottom of the interposer 104 and one or more pads 222 on a top of the interposer 104. By the pads 206, the interposer 104 is configured to couple to the printed circuit board 102 (e.g., by the solder balls 112). By the pads 222, the interposer 104 is configured to couple to the die 106 (e.g., by the interconnects 108). The vias 224 may be provided for routing between the pads and the various metal layers of the interposer 104. For example, the vias 224 may connect the passive devices 110 to the printed circuit board 102 directly or indirectly by way of the metal layers. As may be understood, the specific routing may be based on the desired circuit connection such that the various figures provided herein are not intended to be limiting. The interposer 104 may include substantially fewer layers than the die 106. For example, the interposer may include between four and five layers, or more with the die 106 including substantially more layers. In this regard, the layers of the die 106 may be provided for the various active devices of the die 106.

The passive devices 110 may be integrated into one or more of the substrate 202 and one or more layers of the multilayer structure 204. In embodiments, the passive devices 110 are integrated into a top layer of the multilayer structure 204. The passive devices 110 may be arranged on the top surface to form an array 210. Although not depicted, the vias 224, together with one or more metallization layers, may couple the passive devices 110 of the array 210 to the printed circuit board 102. As used herein, coupling by a via is not intended to be limited to a direct connection between the via and the associated component(s). For instance, the vias may connect to pads and subsequently the associated component(s). By way of another instance, multiple vias may be interconnected through traces and the like. The via may thus be coupled to the component(s) in any number of manners.

The array 210 may include a collection of the passive devices 110 which are grouped together on a top surface of the interposer 104. Any number of the integrated passive devices 110 may be formed in the array during a wafer processing step. Furthermore, multiple types of passive devices may be integrated into a same layer. The array 210 may generally include any suitable arrangement of the passive devices 110. For example, the array may be a rectangular array with a first number of the passive devices 110 along the width of the array and a second number of the passive devices 110 along the length of the array. It is further contemplated that other dimensional arrays may be suitable for the array 110, such that the recitation of rectangular array is not intended to be limiting. The size, position, and arrangement of the passive devices in the array is not intended to be limiting. The array 210 may be positioned in any number of positions on the top surface of the interposer 104. The interposer 104 may also include any number of the arrays 210. Furthermore, the passive devices 110 within the array 210 may include values (e.g., resistances, capacitances, inductances) which are substantially similar or may include values which are different. The passive devices 110 within the array 210 may also include one or more of resistances, inductances, and capacitances. As depicted, the resistors, inductors, and capacitors may be grouped into arrays which share a common resistance, inductance, or capacitance property, although this is not intended to be limiting. The resistors, inductors, and capacitors may also be grouped into arrays which do not share a common property. For example, any number of resistors, inductors, and capacitors may be grouped in the array 210 to achieve a property which includes a capacitance, resistance, and/or inductance.

One or more of the passive devices 110 of the array 210 may be connected by a trace 212. The trace 212 may be formed on the top layer by mask lithography, or a similar fabrication process. The trace 212 may include any trace material, such as, but not limited to, a copper trace. The trace 212 may connect the passive devices 110 to one or more pads 222 on which the die 106 is coupled. The trace 212 may include a series and/or a parallel connection between any number of the passive devices 110. The property of the array 210 may thus be set based on the arrangement of the trace 212 connecting the passive devices 110 in parallel and/or in series. To achieve the desired property, any number of the array 210 may be connected. The trace 212 may also connect to only a portion of the passive devices contained in the array 210. The remaining components of the array may then be left unused on the interposer.

The array 210 may also include a number of passive devices 110 which are not connected by the trace 212 (also referred to as connected out). The passive devices 110 which are not connected by the trace 212 may be provided to adjust the property of the array 210 in an additional mask fabrication without refabricating an underlying layer of the interposer 104. Thus, the passive devices 110 may be integrated into the interposer 104 and used to change the properties of the array 210 and subsequently for tuning the performance of the die 106. The ability to adjust the property of the array 210 is particularly beneficial in radio frequency (RF) applications, because in RF applications the properties may be adjusted to achieve an improved RF performance more rapidly without requiring a redesign and refabrication of the die 106. In this regard, RF applications may use iterative tuning which may be more rapidly accomplished by the use of the interposer 104 and changing the top mask of the interposer 104.

The passive devices 110 may be arranged to form one or more types of arrays, such as, but not limited to, an array 210a including one or more resistors, an array 210b including one or more capacitors, or an array 210c including one or more inductors. The array 210a may include one or more thin-film resistors 214, and the like. The array 210b may include one or more deep-trench capacitors 216, MIM capacitors 218, metal-oxide-semiconductor (MOS) capacitor, metal fringe capacitors, and the like. For example, the MIM capacitor 218 may include two metal plates (e.g., electrodes) each on a separate layer of the multilayer structure. The metal plates may be separated by a dielectric layer. The dielectric layer separating the metal plates may be formed of a material with a different dielectric constant than the dielectric 208 of the multilayer structure. The metal plates may be formed of the same material as the metal trace or a different material. Although the capacitor array is described as including MIM capacitors, this is not intended as a limitation of the present disclosure. By way of another example, the deep-trench capacitor 216 may include a trench with two sides of metal material (e.g., electrodes) filled by a dielectric material and extending between from the top layer through one or more lower layers. Thus, a trench may be formed in the substrate 202 with the two sides of metal material and the dielectric. The array 210c may include one or more inductors, such as planar spiral inductors 220, and the like. The inductors may be provided across one or more metal layers. For example, the inductor may include a two-dimensional coil structure or a three-dimensional coil structure. The three-dimensional coil structure may be provided across multiple metal layers which may be connected between the metal layers by vias. As may be understood, where the passive device 110 includes an inductor, the inductor may generally include any shape for generating an inductance value. Thus, the array 210a, the array 210b, and the array 210c may be provided for adjustable properties including resistance, capacitance, and inductance for the die 106.

Integrating the passive devices 110 into the top layer of the interposer 104 may be advantageous for reducing a package height. To reduce the package height, one or more of the passive devices 110 may be placed underneath the die 106. For example, FIG. 2A depicts one or more thin-film resistors 214 of the array 210a as being disposed below the die 106.

Although the passive devices 110 are described as being integrated into the top layer of the interposer 104, this is not intended as a limitation of the present disclosure. The multilayer structure 204 may also include any number of the passive devices 110 integrated into one or more lower layers of the multilayer structure 204 below the top layer and/or into the substrate 202. For example, the lower layers of the multilayer structure 204 may include a MIM capacitor, deep-trench capacitor, a thin film resistor, an inductor, or another passive device, which may be formed from one or more of the metal layers. Furthermore, the substrate 202 may include one or more of the passive devices 110. For example, the substrate 202 may include a deep trench capacitor, or another passive device. Where the passive devices 110 are provided below the top layer, such passive devices 110 may then be connected between the printed circuit board 102 and the die 106 for forming a circuit connection. For example, the passive devices 110 within the lower metallization layers and the substrate may be connected out during fabrication of the metallization layers.

As depicted in FIG. 2D, the substrate 202 may include any number of the trench capacitors 216. The trench capacitors 216 may be arranged to form one or more of the arrays 210, such as a capacitor array. For example, the trench capacitors 216 are depicted as being in four groups each with three trench capacitors arranged in parallel, although this is not intended to be limiting. As may be understood, the interposer 104 may generally include any number of the groups. Furthermore, the interposer 104 may include any arrangement of the trench capacitors in series and/or in parallel to achieve a desired capacitance value. The trench capacitors 216 in the substrate 202 may be coupled to the pad 206 by one or more vias (e.g., a through via connected to an electrode of the trench capacitor). Similarly, the trench capacitors 216 may be fanned out to the top surface of the interposer 104 through one or more traces and vias 224 within the dielectric of the multilayer structure 204. For example, the electrodes of the trench capacitor 216 may be connected to the top surface. By designing the metal layers in the multilayer structure 204, the trench capacitor arrays may be connected in parallel or in series. In some instances, one or more of the trench capacitors 216 may be routed in parallel or in series to a location on the top surface of the multilayer structure 204. The capacitor array may then be connected to the pads 222 by the trace 212 on the top surface. Advantageously, a capacitance value for the interposer 104 may be changed by adjusting the path of the trace 212.

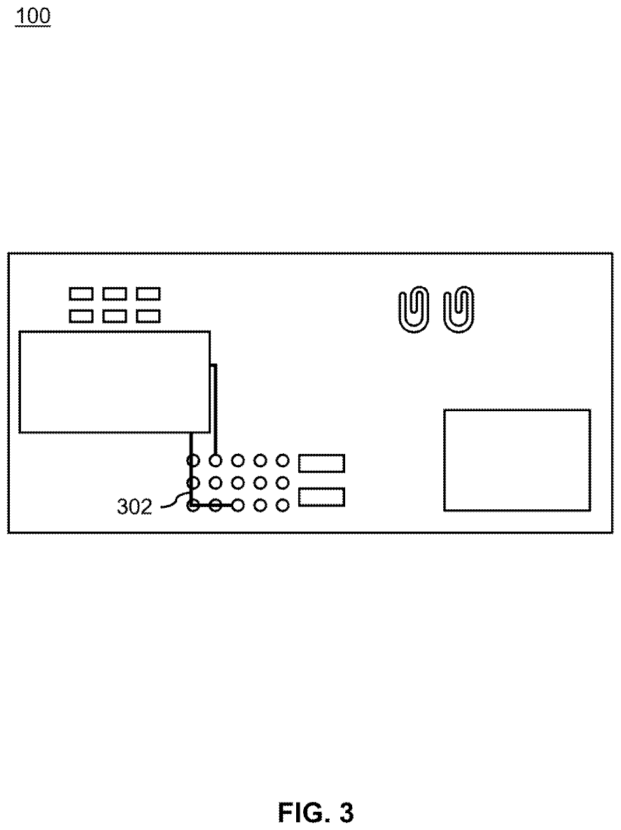

Referring now to FIG. 3, the value of the array 210b is to be changed to tune the die 106. The value may be changed by adding a new mask to the top of the interposer 104, thereby extending the trace 212 to form a trace 302. Advantageously, additional of the passive devices 110 may be added in series or parallel to achieve the new property without having to redo the lower metallization layers below the top layer. The interposer 104 may thus provide an ability to rapidly prototype and produce the package 100.

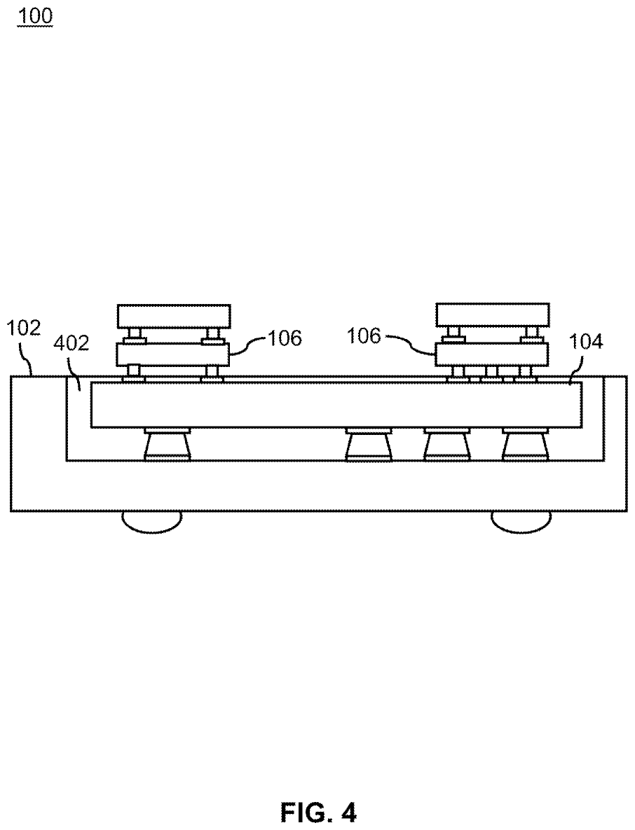

Referring now to FIG. 4, the package 100 is described, in accordance one or more embodiments of the present disclosure. In embodiments, the printed circuit board 102 may include a cavity 402. The cavity 402 may be formed in any manner, such as, but not limited to, routing, lamination, or the like. The interposer 104 may be coupled to the printed circuit board 102 in the cavity 402. Coupling the interposer 104 in the cavity 402 may be advantageous for reducing a height of the package 100. In this regard, the depth of the cavity 402 may be based on the thickness of the interposer 104, although this is not intended to be limiting. In some instances, the cavity 402 includes a sufficient depth such that the top surface of the interposer 104 is below the top surface of the printed circuit board 102. In this regard, the interposer 104 may be considered embedded within the printed circuit board 102. It is further contemplated that fewer layers of the printed circuit board 102 may be removed such that the top surface of the interposer 104 may be disposed above the top surface of the printed circuit board 102. In this regard, the interposer 104 may be considered partially embedded within the printed circuit board 102. One or more die of the die 106 may then be stacked on the interposer 104. Although the printed circuit board 102 is described as including the cavity 402, this is not intended as a limitation of the present disclosure. Thus, the interposer 104 may be assembled on the printed circuit board 102 or in the cavity 402. Furthermore, the interposer 104 may cover a partial area of the printed circuit board 102 or the entire area of the printed circuit board 102.

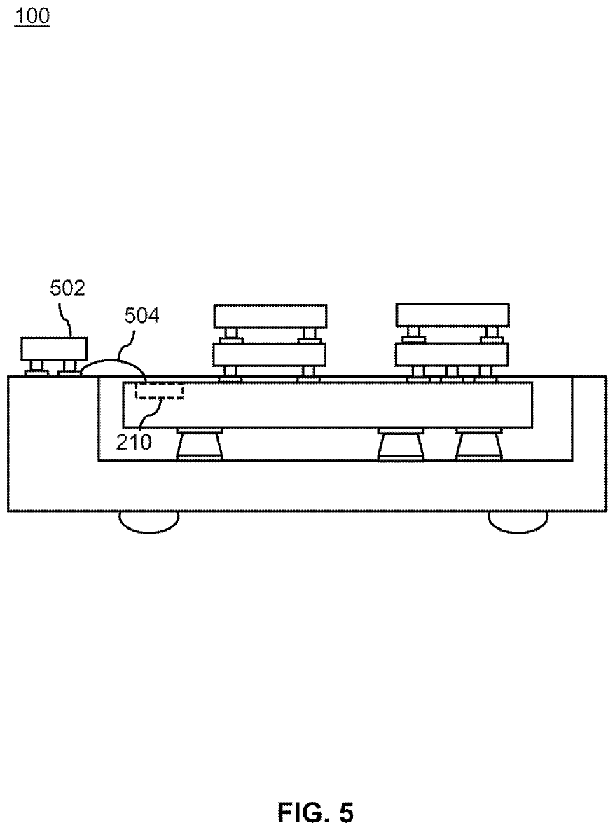

Referring now to FIGS. 5-6B, the package 100 is further described, in accordance with one or more embodiments of the present disclosure. In embodiments, one or more of the passive devices 110 of the array 210 are used to serve an additional die 502. For example, the additional die 502 may be coupled to the printed circuit board 102. The additional die 502 may be coupled to the top or bottom surface of the printed surface board 102. Serving the additional die 502 by the array 210 may be advantageous in using the passive devices 110 which are not currently connected to the trace 212 and would otherwise be unused by the die 106.

As depicted in FIG. 5, the unused passive devices may be connected to one or more of the printed circuit board 102 or the additional die 502 by a wire-bond 504. Connecting the unused passive devices of the array 210 to the additional die 502 by the wire-bond 504 may provide a relatively low complexity connection for connecting out the otherwise unused passive devices. In some instances, the interposer 104 may be embedded in the printed circuit board 102 such that a length of the wire-bond 504 may be reduced, thereby minimally impacting package performance due to impedance.

As depicted in FIGS. 6A-6B, the interposer 104 may include a through via 602. The through via 602 may be connected from the top surface to the bottom surface of the interposer 104. The through via 602 may be formed in the interposer 104 as a reserve for connecting out and repurposing the passive devices 110 of the array 210 which are unused by the die 106. A trace 604 may then be added to the top surface connecting the through via 602 and one or more of the passive devices 110 on the top surface of the interposer 104. The through via 602 may also be coupled to the pad 206 disposed on the bottom of the substrate 202 by which the interposer 104 is coupled to the printed circuit board 102. In this regard, passive devices 110 which are not being used by the die 106 may instead serve the additional die 502 by way of the through via 602 and the printed circuit board 102. The ability to serve the additional die 502 may be advantageous in both reusing passive devices which would otherwise be unused and reducing a need for discrete passive components which would otherwise be coupled to the printed circuit board 102. In a similar manner, the value for the passive devices 110 coupled to the additional die 502 may then be controlled by changing the trace 604. Thus, the passive devices 110 on the top layer of the interposer 104 may be coupled to the additional die 502 by the wire-bond 504, the through via 602 with trace 604, and the like.

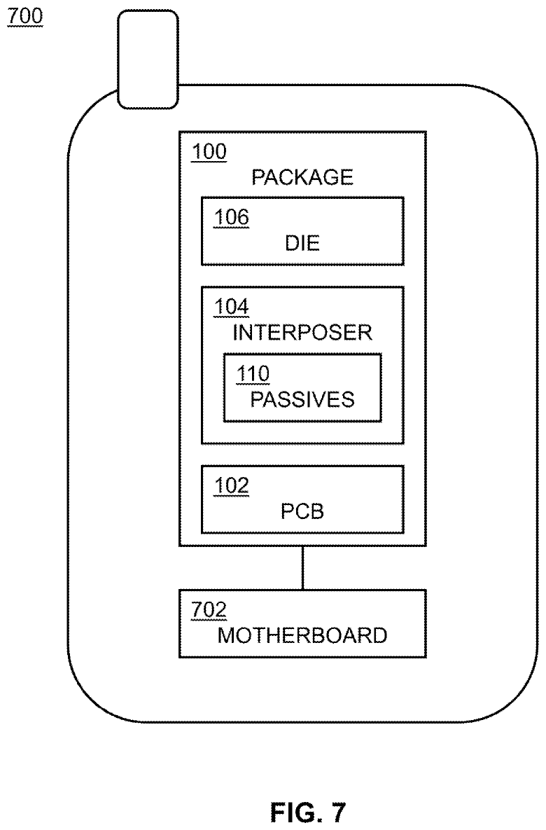

Referring now to FIG. 7, a communication device 700 (is described, in accordance with one or more embodiments of the present disclosure. In some instances, the package 100 may be couplable to a motherboard 702 of the communication device 700. The printed circuit board 102 may be coupled to the motherboard 702 by pads disposed on the bottom of the printed circuit board 102. In some instances, the package 100 may include a radio frequency (RF) module for filtering or amplifying a signal of the communication device 700, such that the package 100 may be considered a component of a RF front end. The die 106 may thus be configured to filter a radio frequency signal or amplify a power of the radio frequency signal of the motherboard 702. It is further contemplated that the package 100 may perform one or more additional functions for the communication device 700. It is further contemplated that various embodiments of the package 100 may be useable outside of the context of the communication device 700. The communication device 700 may generally include any type of device configured to communicate by transmitting or receiving a signal (e.g., digital, analog, etc.) over a medium (e.g., wired, wireless, etc.), such as, but not limited, a cellular phone, a modem, a network interface, and the like. In some instances, the communication device 700 is configured to communicate by the RF front end.

Referring generally again to FIGS. 1-7, although much of the present disclosure is directed to passive devices 110 integrated in the interposer 104, this is not intended as a limitation of the present disclosure. In this regard, the printed circuit board 102 may include one or more passives, such as discrete passive components or integrated passive devices. However, the ability to integrate the passive devices within the interposer 104 may reduce a need for the printed circuit board 102 to include the discrete passive components. Similarly, the die 106 may include one or more passive components. However, providing the passive devices 110 within the interposer 104 may be advantageous in tuning the die 106 without refabricating the die 106 for tuning purposes.

The printed circuit board 102 may include one or more metal layers separated by one or more insulating layers (not depicted). The metal layers may be formed from any electrically conductive material compatible with fabrication of printed circuit boards, such as, but not limited to, copper, gold, silver, aluminum, and the like. Similarly, the insulating layers may be formed by any electrically insulating material compatible with fabrication of printed circuit boards, such as, but not limited to, a resin material (e.g., FR-4), and the like. The metal layers may generally be fabricated by any printed circuit board fabrication process. The printed circuit board 102 may also include multiple layers of the metal layers and the insulating layers, such that the printed circuit board 102 may be considered a multilayer PCB.

The interposer 104 may fan out a pitch from the die 106 to the printed circuit board 102. Fanning out the pitch may be advantageous for connection purposes. In this regard, the die 106 may include contacts which have a much smaller pitch or size as compared to contacts of the printed circuit board 102. The interposer 104 may fan out the signal lines from a fine pitch to a coarse pitch in any manner known in the art. For example, the vias 224 may include, but are not limited to, through-silicon vias (TSV). The printed circuit board 102 may thus communicate various signals between the printed circuit board 102 and the die 106.

As may be understood, the various figures depicted herein are not drawn to scale but are merely provided for illustration. For example, the metallization layers of the interposer 104 may be layered at a ten micron to a hundred of micron scale. The scale of the metal layers may also decrease with changes in wafer fabrication technology. Furthermore, the scale of and the distance between the metal layers may be different across the layers. Furthermore, the various figures provided herein are merely illustrative of the various embodiments described herein.

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A package comprising:
a printed circuit board;
an interposer coupled to the printed circuit board, the interposer including:
a substrate including at least one via;
a multilayer structure disposed above the substrate, the multilayer structure including a top layer with an array including a plurality of passive devices integrated into at least one of the substrate or a dielectric of the multilayer structure, wherein the at least one via couples the plurality of passive devices to the printed circuit board; and
a trace disposed above the multilayer structure and connecting at least one passive device of the plurality of passive devices to a pad disposed above the multilayer structure; the array including a property defined by the at least one passive device which is connected to the trace; and
a die coupled to the pad.

2. The package of claim 1, wherein the array includes at least one additional passive device which is not connected to the pad by the trace, wherein the property of the array is adjustable by connecting the at least one passive device with the at least one additional passive device by the trace for tuning the die.

3. The package of claim 1, further comprising an additional die coupled to the printed circuit board; wherein the array includes at least one additional passive device which is not connected to the pad by the trace, wherein the at least one additional passive device is coupled to the additional die.

4. The package of claim 3, wherein the at least one additional passive device is coupled to the additional die by a wire-bond.

5. The package of claim 3, wherein the interposer includes a through via and an additional trace disposed above the multilayer structure; wherein the additional trace connects the through via and the at least one additional passive device; wherein the at least one additional passive device is coupled to the additional die by the through via.

6. The package of claim 1, wherein the interposer is a passive interposer.

7. The package of claim 1, wherein the printed circuit board defines a cavity, wherein the interposer is disposed in the cavity.

8. The package of claim 1, wherein the die is coupled to the pad by an interconnect.

9. The package of claim 1, wherein the package comprises a radio frequency module.

10. An interposer comprising:
a substrate including at least one via;
a multilayer structure disposed above the substrate, the multilayer structure including a top layer with an array including a plurality of passive devices integrated into at least one of the substrate or a dielectric of the multilayer structure, wherein the at least one via couples the plurality of passive devices to a first pad disposed on a bottom of the substrate by which the interposer is configured to couple to a printed circuit board; and
a trace disposed above the multilayer structure and connecting at least one passive device of the plurality of passive devices to a second pad disposed above the multilayer structure by which the interposer is configured to couple to a die; wherein the array includes a property defined by the at least one passive device connected to the trace.

11. The interposer of claim 10, wherein the array further comprises at least one additional passive device which is not connected to the second pad by the trace, wherein the property of the array is adjustable by connecting the at least one passive device with the at least one additional passive device by the trace for tuning the die.

12. The interposer of claim 10, further comprising a through via and an additional trace disposed above the multilayer structure; wherein the array includes at least one additional passive device which is not connected to the second pad disposed above the multilayer structure by the trace; wherein the additional trace connects the through via and the at least one additional passive device; wherein the through via is connected to the first pad disposed on the bottom of the substrate.

13. The interposer of claim 10, wherein the substrate is one of a silicon substrate or a glass substrate.

14. The interposer of claim 10, wherein the property of the array is a resistance, wherein the at least one passive device includes a thin-film resistor.

15. The interposer of claim 10, wherein the property of the array is a capacitance, wherein the at least one passive device includes a metal-insulator-metal capacitor integrated into the dielectric or a deep trench capacitor integrated into the substrate.

16. The interposer of claim 10, wherein the property of the array is an inductance, wherein the at least one passive device includes an inductor.

17. The interposer of claim 10, wherein the substrate further comprises one or more additional passive components.

18. The interposer of claim 17, wherein the one or more additional passive components include a deep trench capacitor.

19. A communication device comprising:
a motherboard; and
a radio frequency module including:
a printed circuit board coupled to the motherboard;
an interposer coupled to the printed circuit board, the interposer including:
a substrate including at least one via;
a multilayer structure disposed above the substrate, the multilayer structure including a top layer with an array including a plurality of passive devices integrated into at least one of the substrate or a dielectric of the multilayer structure, wherein the at least one via couples the plurality of passive devices to the printed circuit board; and
a trace disposed above the multilayer structure and connecting at least one passive device of the plurality of passive devices to a pad disposed above the multilayer structure; the array including a property defined by the passive device which is connected to the trace; and
a die coupled to the trace.

20. The communication device of claim 19, wherein the die is configured to at least one of filter a radio frequency signal of the motherboard or amplify a power of the radio frequency signal.
